(19) United States
(12) Patent Application Publication
(10) Pub. No.: US 2009/0211619 A1
(43) Pub. Date: Aug. 27, 2009

(54) Thermoelectric Material and Device Incorporating Same

(75) Inventors: Jeff Sharp, Murphy, TX (US); Alan J. Thompson, Forney, TX (US)

Correspondence Address: BAKER BOTTS L.L.P., 2001 ROSS AVENUE, SUITE 600, DALLAS, TX, 75201-2980, US

(73) Assignee: Marlow Industries, Inc., Dallas, TX (US)

(21) Appl. No.: 12/391,037

(22) Filed: Feb. 23, 2009

Related U.S. Application Data
(60) Provisional application No. 61/031,518, filed on Feb. 26, 2008.

(51) Int. Cl. H01L 35/20; H01L 35/34

(52) U.S. Cl. 136/240; 136/201

(57) ABSTRACT

A thermoelectric device includes a plurality of thermoelectric elements coupled between a first plate and a second plate. The plurality of thermoelectric elements are electrically interconnected with one another by a plurality of electrical interconnects and the plurality of thermoelectric elements include at least one thermoelectric element comprising a material having the formula AₓB_{y}C_{z}, where A is one or more components selected from the group consisting of group II cations and mixtures thereof, B is one or more components selected from the group consisting of group I cations and mixtures thereof, and C is one or more components selected from the group consisting of group V anions and mixtures thereof, and x, y, and z are molar ratios.

### CROSS REFERENCE TO RELATED APPLICATIONS

This application claims the benefit under 35 U.S.C. § 119(e) of U.S. Provisional Application No. 61/031,518, entitled “Thermoelectric Material and Device Incorporating Same,” filed Feb. 26, 2008.

### TECHNICAL FIELD

The present disclosure relates to materials having thermoelectric properties for use in fabricating thermoelectric devices and more specifically to a MgAgSb-based thermoelectric material and device incorporating the same.

### BACKGROUND

The basic theory and operation of thermoelectric devices has been developed for many years. Presently available thermoelectric devices typically include an array of thermocouples which operate in accordance with the Peltier effect. Thermoelectric devices may also be used for applications such as temperature control, power generation, and temperature sensing.

Thermoelectric devices may be described as essentially small heat pumps that follow the laws of thermodynamics in the same manner as mechanical heat pumps, refrigerators, or any other apparatus used to transfer heat energy. A principal difference is that thermoelectric devices function with solid state electrical components (thermoelectric elements or thermocouples) as compared to more traditional mechanical/fluid heating and cooling components. The efficiency of a thermoelectric device is generally limited to its associated Carnot cycle efficiency, reduced by a factor which is dependent upon the thermoelectric figure of merit (ZT) of materials used in fabrication of the associated thermoelectric elements. Typically, a thermoelectric device incorporates both a P-type semiconductor alloy and an N-type semiconductor alloy as the thermoelectric materials. Materials and methods used to fabricate other components such as electrical connections, hot plates, and cold plates may also affect the overall efficiency of the resulting thermoelectric device.

Previous thermoelectric devices have used materials such as alloys of Bi₂Te₃, PbTe, SiGe, and BiSb for the thermoelectric elements. However, many of these materials contain unfavorable constituents such as germanium, tellurium, and lead. Commercially available thermoelectric materials are generally limited to use in a temperature range between 200K and 1300K with a maximum ZT value of approximately one.

### SUMMARY

In particular embodiments, the present disclosure may provide a thermoelectric device that includes a plurality of thermoelectric elements coupled between a first plate and a second plate. The plurality of thermoelectric elements may be electrically interconnected with one another by a plurality of electrical interconnects, and the plurality of thermoelectric elements may include at least one thermoelectric element comprising a material having the formula AₓB_{y}C_{z}, where A is one or more components selected from the group consisting of group II cations and mixtures thereof, B is one or more components selected from the group consisting of group I cations and mixtures thereof, and C is one or more components selected from the group consisting of group V anions and mixtures thereof, and x, y, and z are molar ratios. For example, A may be one or more components selected from the group consisting of Mg, Ca, Sr, Ba, Eu, Yb, Ti, Mn, Fe, Ni, Cu, Zn, Cd, Hg, and mixtures thereof, B may be one or more components selected from the group consisting of Na, K, Rb, Cs, Cu, Ag, Au, and mixtures thereof, and C may be one or more components selected from the group consisting of As, Sb, Bi, and mixtures thereof.

In particular embodiments, the present disclosure may further provide a thermoelectric element that includes a material having the formula AₓB_{y}C_{z}, wherein A is one or more components selected from the group consisting of group II cations and mixtures thereof, B is one or more components selected from the group consisting of group I cations and mixtures thereof, and C is one or more components selected from the group consisting of group V anions and mixtures thereof, and x, y, and z are molar ratios. For example, A may be one or more components selected from the group consisting of Mg, Ca, Sr, Ba, Eu, Yb, Ti, Mn, Fe, Ni, Cu, Zn, Cd, Hg, and mixtures thereof, B may be one or more components selected from the group consisting of Na, K, Rb, Cs, Cu, Ag, Au, and mixtures thereof, and C may be one or more components selected from the group consisting of As, Sb, Bi, and mixtures thereof.

In particular embodiments, the present disclosure may further provide a method that includes providing a material having the formula AₓB_{y}C_{z}, where A is one or more components selected from the group consisting of group II cations and mixtures thereof, B is one or more components selected from the group consisting of group I cations and mixtures thereof, and C is one or more components selected from the group consisting of group V anions and mixtures thereof and x, y, and z are molar ratios. The method further includes using the material as a thermoelectric material. For example, using the material as a thermoelectric material may include applying electrical current to the material and allowing the material to generate a temperature difference between a first side of the material and a second side of the material.

In particular embodiments, the present disclosure may provide a thermoelectric device that includes a plurality of thermoelectric elements coupled between a first plate and a second plate. The plurality of thermoelectric elements may be electrically interconnected with one another by a plurality of electrical interconnects and the plurality of thermoelectric elements may include at least one thermoelectric element comprising a material having the formula A_{x-w}B_{y+w}C_{z-w}D_{w}, where A is one or more components selected from the group consisting of group II cations and mixtures thereof, B is one or more components selected from the group consisting of group I cations and mixtures thereof, C is one or more components selected from the group consisting of group V anions and mixtures thereof, and D is one or more components selected from the group consisting of group VI anions and mixtures thereof, and w, x, y, and z are molar ratios. For example, A may be one or more components selected from the group consisting of Mg, Ca, Sr, Ba, Eu, Yb, Ti, Mn, Fe, Ni, Cu, Zn, Cd, Hg, and mixtures thereof, B may be one or more components selected from the group consisting of Na, K, Rb, Cs, Cu, Ag, Au, and mixtures thereof, C may be one or more components selected from the group consisting of As, Sb, Bi, and mixtures thereof, and D may be one or more components selected from the group consisting of Se, Te, and mixtures thereof.

In particular embodiments, the present disclosure may provide a thermoelectric device that includes a plurality of thermoelectric elements coupled between a first plate and a second plate. The plurality of thermoelectric elements may be electrically interconnected with one another by a plurality of electrical interconnects and the plurality of thermoelectric elements may include at least one thermoelectric element comprising a material having the formula A_{x+w}B_{y-w}C_{z-w}E_{w}, where A is one or more components selected from the group consisting of group II cations and mixtures thereof, B is one or more components selected from the group consisting of group I cations and mixtures thereof, C is one or more components selected from the group consisting of group V anions and mixtures thereof, and E is one or more components selected from the group consisting of group IV anions and mixtures thereof, and w, x, y, and z are molar ratios. For example, A may be one or more components selected from the group consisting of Mg, Ca, Sr, Ba, Eu, Yb, Ti, Mn, Fe, Ni, Cu, Zn, Cd, Hg, and mixtures thereof, B may be one or more components selected from the group consisting of Na, K, Rb, Cs, Cu, Ag, Au, and mixtures thereof, C may be one or more components selected from the group consisting of As, Sb, Bi, and mixtures thereof, and E may be one or more components selected from the group consisting of Si, Ge, Sn, Pb, and mixtures thereof.

In particular embodiments, the present disclosure may provide a thermoelectric device that includes a plurality of thermoelectric elements coupled between a first plate and a second plate. The plurality of thermoelectric elements may be electrically interconnected with one another by a plurality of electrical interconnects and the plurality of thermoelectric elements may include at least one thermoelectric element comprising a material having the formula (AₓB_{y}C_{z})₁₋ₐ(FᵤCᵥ)ₐ, where A is one or more components selected from the group consisting of group II cations and mixtures thereof, B is one or more components selected from the group consisting of group I cations and mixtures thereof, C is one or more components selected from the group consisting of group V anions and mixtures thereof, and F is one or more components selected from the group consisting of group III cations and mixtures thereof, and a, u, v, x, y, and z are molar ratios. For example, A may be one or more components selected from the group consisting of Mg, Ca, Sr, Ba, Eu, Yb, Ti, Mn, Fe, Ni, Cu, Zn, Cd, Hg, and mixtures thereof, B may be one or more components selected from the group consisting of Na, K, Rb, Cs, Cu, Ag, Au, and mixtures thereof, C may be one or more components selected from the group consisting of As, Sb, Bi, and mixtures thereof, and F may be one or more components selected from the group consisting of Al, Ga, In, and mixtures thereof.

Technical advantages of particular embodiments of the present disclosure may include providing a thermoelectric material with better performance characteristics over a range of temperature values as compared to currently existing thermoelectric materials.

Other technical advantages of the present disclosure will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present disclosure and its advantages, reference is now made to the following descriptions, taken in conjunction with the accompanying drawings, in which:

FIG. 1 illustrates an example thermoelectric device that may be built in accordance with a particular embodiment of the present disclosure;

FIG. 2 illustrates a graphical representation of example Seebeck coefficient values (“S”) for a sample of Mg₁Ag₁Sb₁ produced in accordance with the present disclosure measured across a range of temperatures;

FIG. 3 illustrates a graphical representation of example electrical resistivity values and example thermal conductivity values for a sample of Mg₁Ag₁Sb₁ produced in accordance with the present disclosure measured across a range of temperatures;

FIG. 4 illustrates a graphical representation of example ZT coefficient values for a sample of Mg₁Ag₁Sb₁ produced in accordance with the present disclosure measured across a range of temperatures;

FIG. 5 illustrates a graphical representation of measured and anticipated ZT coefficient values for two samples of Mg₁Ag₁Sb₁ produced in accordance with the present disclosure as compared against known ZT values of various P-type materials across a range of temperatures;

FIG. 6 illustrates example power factor values (S²/ρ) for a number of samples of Mg₁Ag₁Sb₁ produced in accordance with the present disclosure;

FIG. 7 illustrates example differential thermal analysis (DTA) and Thermogravimetric Analysis (TGA) curves for a sample of Mg₁Ag₁Sb₁ produced in accordance with the present disclosure;

FIG. 8 illustrates a powder diffraction pattern for a sample of Mg₁Ag₁Sb₁ produced in accordance with the present disclosure for the case of a four-day heat treatment; and

FIG. 9 illustrates a powder diffraction pattern for a sample of Mg₁Ag₁Sb₁ produced in accordance with the present disclosure for the case of a two-week heat treatment.

### DETAILED DESCRIPTION OF EXAMPLE EMBODIMENTS

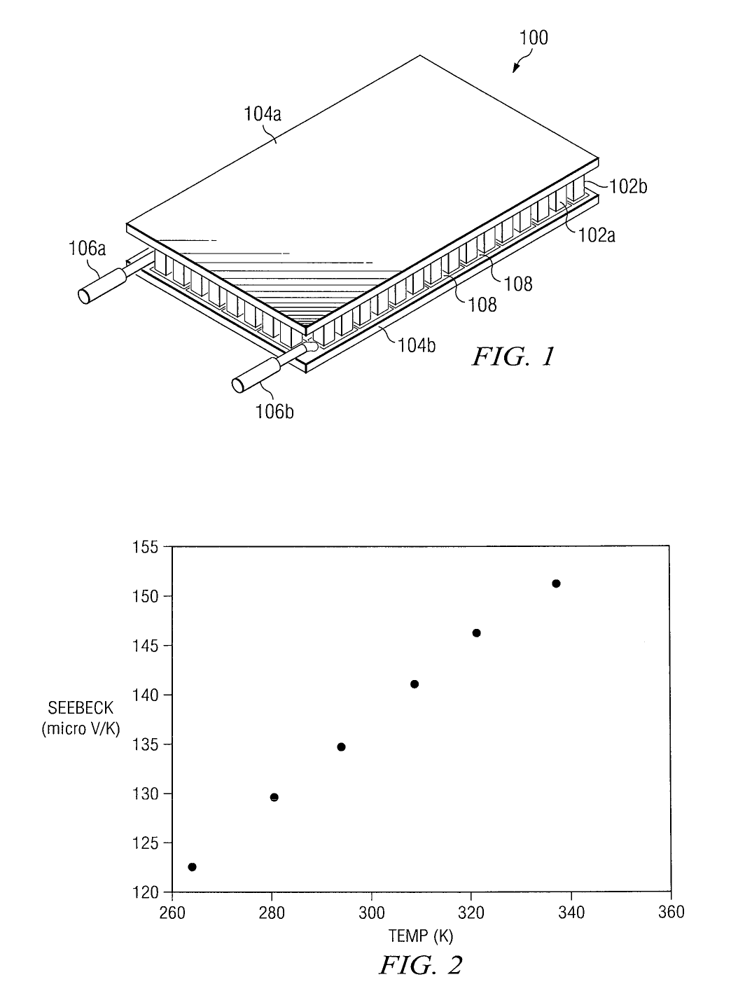

FIG. 1 illustrates an example thermoelectric device 100 fabricated in accordance with a particular embodiment of the present disclosure. Thermoelectric device 100 generally includes a plurality of P-type elements 102a and N-type thermoelectric elements 102b (collectively, thermoelectric elements 102) disposed between a first plate 104a and a second plate 104b (collectively, plates 104). The ends of thermoelectric elements 102 are electrically connected to one another by a series of electrical interconnects 108 composed of an electrically and thermally conductive material such as copper. In particular embodiments, a diffusion barrier (not pictured), such as Nickel, may be deposited between elements 102 and interconnects 108, for example, to prevent the diffusion of copper from interconnects 108 into elements 102. Furthermore, electrical terminals 106a and 106b (collectively, electrical terminals 106) are provided to allow thermoelectric device 100 to be electrically coupled with an appropriate source of electrical power (e.g., a battery that supplies DC current).

Typical applications for thermoelectric device 100 include use as a temperature control device or a power generator. In the former case, when thermoelectric device 100 is connected to a power source, electrical current may pass through thermoelectric elements 102 via electrical interconnects 108. Due to the thermoelectric properties of thermoelectric elements 102, the electrical current from the power source may cause a temperature gradient across thermoelectric elements 102, causing elements 102 to become hot on one end and cold on the other. This collectively causes one of plates 104 (e.g., first plate 104a) to become hot and the other of plates 104 (e.g., second plate 104b) to become cold, depending upon the direction of current flow. Consequently, by coupling an object to one of plates 104, thermoelectric device 100 may be used to control the temperature of the object.

Conversely, to use thermoelectric device 100 as a power generator, thermoelectric device 100 may be subjected to a temperature difference across plates 104. For example, one of plates 104 (e.g., first plate 104b) may be coupled to a heat source. Due to the thermoelectric properties of thermoelectric elements 102, this temperature difference between plates 104 may cause a voltage difference to develop on electrical terminals 106. Consequently, by electrically connecting thermoelectric device 100 to an electrical device such as a rechargeable battery, thermoelectric device 100 may be used to power the device.

One of ordinary skill in the art will appreciate that the above-described embodiments of thermoelectric device 100 were presented for the sake of explanatory simplicity and will further appreciate that the present disclosure contemplates using any suitable number and configuration of components (e.g., elements 102, plates 104, electrical terminals 106, electrical interconnects 108, diffusion barriers, etc.) in thermoelectric device 100 to enable thermoelectric device 100 to be used in any suitable thermoelectric application.

As mentioned above, thermoelectric device 100 includes two or more plates 104 and a plurality of thermoelectric elements 102. Each of plates 104 may be any fixture capable of acting as a substrate for thermoelectric elements 102. As an example and not by way of limitation, a plate 104 may be a rigid sheet of thermally conductive and electrically insulating material such as ceramic. As another example and not by way of limitation, a plate 104 may be composed of a flexible material such as KAPTON™ tape. As yet another example and not by way of limitation, a plate 104 may be an object upon which thermoelectric device is built. In any case, one of skill in the art will appreciate that the present disclosure contemplates plate 104 being any suitable fixture composed of any suitable thermally conductive and electrically insulating material capable of serving as a substrate for thermoelectric elements 102.

Each element 102 may be any fixture or component of thermoelectric material included in thermoelectric device 100. As mentioned briefly above, in a typical construction of thermoelectric device 100, elements 102 may generally include a plurality of alternatingly arranged P-type semiconductor elements 102a and N-type semiconductor elements 102b. By way of explanation, N-type semiconductor materials generally have more electrons than necessary to complete the associated crystal lattice structure, while P-type semiconductor materials generally have fewer electrons than necessary to complete the associated crystal lattice structure. The “missing electrons” are sometimes referred to as “holes.” The extra electrons and extra holes are sometimes referred to as “carriers.” The extra electrons in N-type semiconductor materials and the extra holes in P-type semiconductor materials are the agents or carriers which transport or move heat energy between the hot side of thermoelectric device 100 (e.g., first plate 104a) and the cold side of thermoelectric device 100 (e.g., second plate 104b) through elements 102 when subject to a DC voltage potential. These same agents or carriers may generate electrical power when an appropriate temperature difference is applied to plates 104.

Thermoelectric device 100 also includes a plurality of electrical interconnects 108, which electrically couple thermoelectric elements 102 together, and which may, in some cases, physically couple elements 102 to plates 104. Electrical interconnects 108 may be any electrically conductive fixture capable of transmitting electrical current between thermoelectric elements 102. As an example and not by way of limitation, the electrical interconnects 108 may be a metallization formed on the interior surfaces of plates 104. As an additional example and not by way of limitation, electrical interconnects 108 may be soldered interconnections deposited on thermoelectric elements 102. Electrical interconnects 108 may be composed of any suitable electrically conductive material such as for example, copper, steel, or other suitable metal. In any case, one of skill in the art will appreciate that the present disclosure contemplates the use of any suitable configuration of electrical interconnects 108 composed of any suitable material for electrically connecting elements 102.

In particular embodiments, one or more of elements 102 may be composed of a thermoelectric material based on the family of materials having the general formula AₓB_{y}C_{z}, where A is a group II cation or mixture of group II cations, such as Mg, Ca, Sr, Ba, Eu, Yb, Ti, Mn, Fe, Ni, Cu, Zn, Cd, or Hg; B is a group I cation or mixture of group I cations, such as Na, K, Rb, Cs, Cu, Ag, or Au; C is a group V anion or mixture of group V anions, such as As, Sb, or Bi, and x, y, and z are molar ratios. In particular embodiments, x may range from about 0.9 to about 1.1, y may range from about 0.9 to about 1.1, and z may range from about 0.9 to about 1.1. As an example and not by way of limitation, A may be Mg, B may be Ag, C may be Sb, and x, y, and z may each be about 1 to yield a composition having the general formula of Mg₁Ag₁Sb₁.

As mentioned above, in particular embodiments, each formula component (e.g., A, B, or C) may comprise a mixture of elements. More particularly, where a formula component (e.g., A, B, or C) is a mixture of elements, the sum of the molar ratios of each constituent element in that mixture must be equal to the molar ratio for that formula component (e.g., x, y, or z). As an example and not by way of limitation A may be Mg, B may be a mixture of equal parts of Ag and Cu, C may be Sb, and x, y, and z may each be about 1 to yield a composition having an example formula of Mg₁Ag_{0.5}Cu_{0.5}Sb₁.

It is believed that compounds of the formula AₓB_{y}C_{z} act as semiconductors due to the valence situation of the constituent elements, which include a cation with a valence of 2 (the “A” component), a cation with a valence of 1 (the “B” component), and an anion that needs 3 electrons to complete its valence (the “C” component). That is, AₓB_{y}C_{z} compounds are believed to act as semiconductors because the total number of valence electrons of the cations (e.g., the two valence electrons from the A component and the one valence electron from the B component) equals the number of valence electrons needed by the anion (e.g., the three valence electrons needed by the C component). For each AₓB_{y}C_{z} compound, the particular crystal structure likely determines whether there is a band gap or whether the valence and conduction bands overlap, making a semi-metal or metal. The particular compounds within the AₓB_{y}C_{z} family that are good thermoelectric materials may be determined by performing systematic band structure calculations on the AₓB_{y}C_{z} family of compounds.

In particular embodiments, further thermoelectric materials may be created by maintaining the II-I-V crystal structure of the AₓB_{y}C_{z}, compound while making non-isovalent substitutions. For example, a portion of the group V element (e.g., As, Sb, and Bi) could be replaced with a group VI element (e.g., Se or Te), provided that the fraction of the monovalent cation is increased to maintain charge balance. For example, such combinations may take the form A_{x-w}B_{y+w}C_{z-w}D_{w}, where D is a group VI element, and w is a molar ratio that may range from about 0 to about 1. In the case of the Mg₁Ag₁Sb₁ material, an example formula for such a substitution would be Mg_{1-w}Ag_{1+w}Sb_{1-w}Te_{w}.

In particular embodiments, further thermoelectric materials may be created by replacing a portion of the group V element (e.g., As, Sb, and Bi) in the AₓB_{y}C_{z} compound with a group IV element (e.g., Si, Ge, Sn, or Pb), provided that the fraction of divalent cation is increased to maintain charge balance. For example, such combinations may take the form A_{x+w}B_{y-w}C_{z-w}E_{w}, where E is a group IV element, and w is a molar ratio that may range from about 0 to about 1. In the case of the Mg₁Ag₁Sb₁ material, an example formula for such a substitution would be Mg_{1+w}Ag_{1-w}Sb_{1-w}Sn_{w}.

In particular embodiments, further thermoelectric materials may be created by alloying AₓB_{y}C_{z} compounds with a compound selected from the family of compounds having the general formula FᵤCᵥ, where F is a group III cation or mixture of group III cations, such as Al, Ga, In, and C is a group V anion or mixture of group V anions, such as As, Sb, or Bi, and u and v are molar ratios. In particular embodiments, u and v may both range from about 0.9 to about 1.1. Compounds in the FᵤCᵥ family generally form in a zinc-blend structure. Although compounds in the FᵤCᵥ family may not be good candidates for use as a thermoelectric material, it is believed that alloying certain compounds in the FᵤCᵥ family with certain compounds in the AₓB_{y}C_{z} family while maintaining the II-I-V crystal structure of the AₓB_{y}C_{z} compound may reduce the thermal conductivity and raise the ZT value of the resultant compound. For example, such combinations may take the form (AₓB_{y}C_{z})₁₋ₐ(FᵤCᵥ)ₐ, where u, v, x, y, and z are each range from about 0.9 to about 1.1 and a ranges from about 0 to about 0.5. In the case of the Mg₁Ag₁Sb₁ material, an example formula for such a substitution would be (Mg₁Ag₁Sb₁)_{0.9}(In₁Sb₁)_{0.1}.

Another possible chemistry variant that may produce a semiconductor with similar crystal structure may be a III-I-IV compound. As an example and not by way of limitation, a III-I-IV semiconductor compound may be ScAgSn.

Of the AₓB_{y}C_{z} family of compounds presented, one example compound having good thermoelectric properties may be formed where A is Mg, B is Ag, and C is Sb, and x, y, and z are each approximately 1. For example, an ideal formula for this material may be Mg_{1.0}Ag_{1.0}Sb_{1.0}, though certain non-ideal factors such as vacancies, interstitials, or substitutions may cause deviations.

Generally, any suitable method may be used to form the thermoelectric materials of the present disclosure. In a particular embodiment, a MgAgSb material having an approximate formula of Mg₁Ag₁Sb₁ may be created according to the following process. First, substantially equal parts of Mg, Ag, and Sb (e.g., a 1:1:1 molar ratio) may be loaded into a BN crucible. The crucible may then be placed in a quartz tube, covered, and sealed under argon. Once the material-laden crucible has been sealed in the quartz tube, the sample may be heated to about 950° C. for several hours, after which, the sample may be air-cooled to room temperature (e.g., about 22° C.).

Once the MgAgSb material has cooled, the MgAgSb material may be crushed in a nitrogen atmosphere comprising 30 to 50 parts per million oxygen. The crushed MgAgSb material may then be powdered to a particle size of approximately 50 microns and hot pressed for a first time. The first hot pressing of the MgAgSb material may occur, for example, in a nitrogen atmosphere from about 300° C. to about 350° C. at a pressure of 62,000 psi for a duration of approximately four hours. The MgAgSb material may then be heat-treated at about 300° C. for fourteen days. In particular embodiments, the MgAgSb material may be powdered a second time to a particle size of approximately 50 microns and hot pressed for a second time for a duration of approximately 1 day at 300° C. and at a pressure of 63,000 psi. In particular embodiments, one or more of the hot pressing steps may include hot isostatic pressing (HIP), in which the sample of MgAgSb material may be pressed equally from all directions by immersion in a pressurized fluid. HIP may provide certain advantages over other methods of processing such as uniaxial pressing and may lead to reduction of grain boundary resistance and/or micro-cracks.

In particular embodiments, the above-described method of production may produce nearly phase-pure MgAgSb material, as may be judged by optical microscopy, scanning electron microscopy and Energy Dispersive X-ray analysis performed in a scanning electron microscope.

One of ordinary skill in the art will appreciate that the above-described methods for forming Mg₁Ag₁Sb₁ were presented for the sake of explanatory clarification and will further appreciate that the present disclosure contemplates the use of any suitable method of forming Mg₁Ag₁Sb₁.

Preliminary tests reveal that the crystal structure of Mg₁Ag₁Sb₁ appears to be cubic and may be, for example, a primitive cubic derivative of the face-centered cubic anti-fluorite structure adopted by the Mg₂X family of materials where X is selected from the group consisting of Si, Ge, Sn, or Pb. Given the similar size of Sn to Sb and Mg to Ag, it is possible that Mg₁Ag₁Sb₁ may be derived from Mg₂Sn by substitution.

In particular embodiments, Mg₁Ag₁Sb₁ may be alloyed with the various anti-fluorite Mg₂X compounds mentioned above since Mg₂Sn, along with Mg₂Ge, Mg₂Si, and Mg₂Pb, have an anti-fluorite structure, and Mg₁Ag₁Sb₁ likely possesses a more complicated derivative of the anti-fluorite structure. Mg₂Sn and Mg₂Si have been found to have good thermoelectric properties at approximately 600 K. By alloying Mg₁Ag₁Sb₁ with an anti-fluorite compound (e.g., an Mg₂X compound), it may be possible to reduce the thermal conductivity of the anti-fluorite compound. Alloys at or near the composition Mg₄SnSi have been found to have ZT of about 1.1 to about 1.2 at about 620 K, and with significant potential for thermal conductivity reduction.

### EXAMPLES

To test the properties of a Mg₁Ag₁Sb₁ compound produced in accordance with the present disclosure, at least 138 samples have been created and tested. Of those samples, at least one sample has yielded a ZT of approximately 0.5 at 340 K. In particular embodiments, the Mg₁Ag₁Sb₁ material may exhibit P-type conduction and may be used in a wide variety of thermoelectric applications. As an example and not by way of limitation, the Mg₁Ag₁Sb₁ material may be used in thermoelectric cooling applications and thermoelectric power generation applications. Though the present disclosure contemplates any suitable use of Mg₁Ag₁Sb₁ in any suitable thermoelectric application, particular embodiments of the Mg₁Ag₁Sb₁ material may be particularly well suited as a thermoelectric power generation material for use up to 300° C.

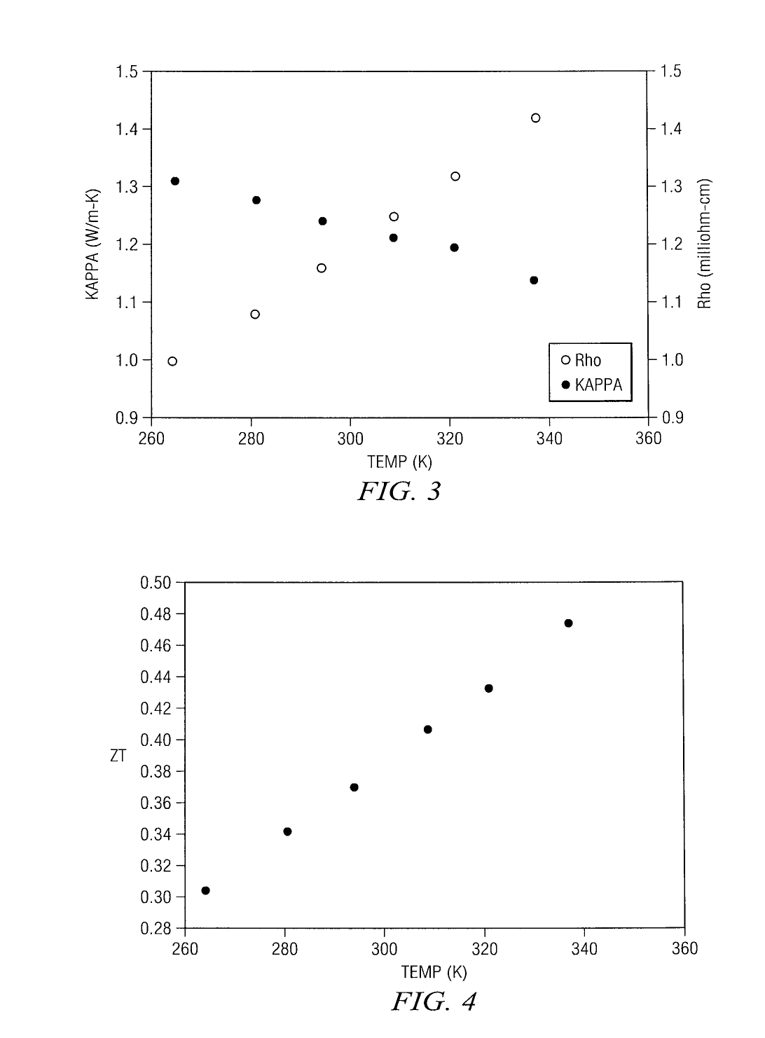

FIGS. 2-4 each display various performance characteristics of a sample of Mg₁Ag₁Sb₁ produced in accordance with the present disclosure. In particular, FIG. 2 illustrates a graphical representation of Seebeck coefficient values (“S”) for the sample of the Mg₁Ag₁Sb₁ material measured across a range of temperatures. FIG. 3 illustrates a graphical representation of example electrical resistivity values (“ρ”) illustrated as light circles and example thermal conductivity values (“Kappa”) illustrated as dark circles for the sample of the Mg₁Ag₁Sb₁ material measured across a range of temperatures. FIG. 4 illustrates a graphical representation of ZT coefficient values for the sample of the Mg₁Ag₁Sb₁ material measured across a range of temperatures, wherein ZT is a dimensionless figure of merit used for thermoelectric materials.

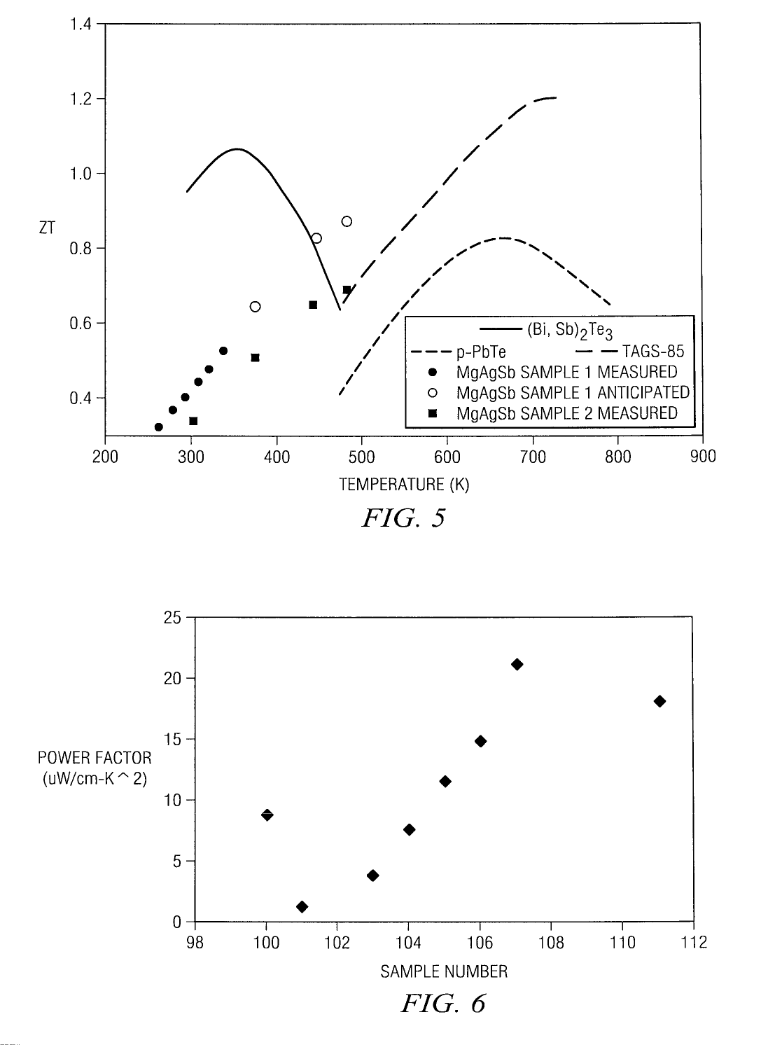

In particular embodiments, a sample of MgAgSb material having an average Mg₁Ag₁Sb₁ composition may possess a ZT of approximately 0.5 at approximately 340 K. As will be appreciated by one of skill in the art, ZT is an increasing function of temperature, and particular embodiments of the Mg₁Ag₁Sb₁ material may possess ZT values greater than 0.5 at temperatures above 340 K and ZT values greater than 1.0 at temperatures above 400 K. In particular embodiments, results similar to those above may be achieved using samples of the Mg₁Ag₁Sb₁ material that are predominately single phase, and that may have relatively poor grain boundaries. By increasing the sample quality of the Mg₁Ag₁Sb₁ material, such as for example by reducing or eliminating oxide impurities, it may be possible to achieve ZT values greater than 0.9 at or near room temperature (e.g., 294 K). As depicted in FIG. 5 below, measurements at higher temperatures show that particular embodiments of the Mg₁Ag₁Sb₁ material may have a ZT value greater than that of other thermoelectric materials over particular ranges of temperatures.

FIG. 5 illustrates a graphical representation of measured and anticipated ZT values for two test samples of Mg₁Ag₁Sb₁ produced in accordance with the present disclosure as compared against known ZT values of other P-type materials across a range of temperatures. In particular, the solid black circles represent measured ZT values for a first test sample of Mg₁Ag₁Sb₁, the open circles represent anticipated ZT values for the first test sample of Mg₁Ag₁Sb₁ at higher temperatures, and the black squares represent measured ZT values obtained for a second test sample of Mg₁Ag₁Sb₁ having a similar carrier concentration to the first sample and a higher resistivity value, tested at higher temperatures. In particular, at about 335 K, the first test sample of Mg₁Ag₁Sb₁ had a resistivity value of about 1.16 milliohm-cm, and the second test sample of Mg₁Ag₁Sb₁ had a resistivity value of about 1.51 milliohm-cm. The Seebeck coefficient was about 150 microVolts/K for both the first test sample and the second test sample of Mg₁Ag₁Sb₁.

While the measured ZT values for the first test sample of Mg₁Ag₁Sb₁ were only available for temperatures up to about 335 K, one might base the anticipated values on the trend of data points that were obtained for the second test sample. In particular, though the second test sample had a relatively high resistivity of about 1.51 milliohm-cm, it produced a ZT value of about 0.3 at room temperature (e.g., about 294 K) and a ZT value of about 0.7 at about 483 K. Given that the first sample had a lower resistivity and produced a ZT value of about 0.37 at room temperature, it is believed that the first sample would produce a ZT value of about 0.88 at 483 K in keeping with the data trend observed for the second sample.

As illustrated in FIG. 5, the anticipated ZT values of the first sample of Mg₁Ag₁Sb₁ exceed the ZT values of the best prior materials in the vicinity of 473 K. It is believed that improved processing of the Mg₁Ag₁Sb₁ material using, for example, techniques that reduce or eliminate oxide impurities, may result in additional increases in ZT near 300 K, possibly making Mg₁Ag₁Sb₁ superior to Bi₂Te₃—Sb₂Te₃ alloy for cooling applications, such as for example, in telecom laser cooling applications wherein the cold side is near room temperature (e.g., 294 K) and the hot side is around 358 K.

In particular embodiments, Mg₁Ag₁Sb₁ may surpass the Bi₂Te₃—Sb₂Te₃ alloy and the P-type material “TAGS-85” (e.g., (GeTe)₈₅(AgSbTe₂)₁₅) in a temperature interval centered around 473 K. As an example and not by way of limitation, this material may supplant the Bi₂Te₃—Sb₂Te₃ alloy as the P-type material in the lower stage of cascaded power generators or in single-stage generators with hot-side temperature less than approximately 573 K.

FIG. 6 illustrates a range of power factor values (S²/ρ) observed for a number of samples of Mg₁Ag₁Sb₁ created in accordance with the present disclosure. As will be appreciated by one of ordinary skill in the art, for a thermoelectric material, the Seebeck coefficient (S) generally increases as the resistivity (ρ) increases. This relationship follows from the dependence of the Seebeck coefficient and the resistivity on carrier concentration or, equivalently, position of the Fermi level relative to the band edge. As a result of this relationship, a thermoelectric material may exhibit similar power factors over a range of carrier concentrations. That is, S and ρ may both vary with carrier concentration, but in a way that leaves the power factor approximately constant. The power factors of FIG. 6 illustrate large sample-to-sample variation even though only a modest range of carrier concentration values may be present in the Mg₁Ag₁Sb₁ material samples. The scatter in the power factor values may indicate defects in the Mg₁Ag₁Sb₁ material (e.g., multiple phases, high-resistance grain boundaries, and/or cracks). In particular embodiments, certain characteristics of the Mg₁Ag₁Sb₁ material may be altered or improved by removing such defects from the Mg₁Ag₁Sb₁ material.

At least one sample of the Mg₁Ag₁Sb₁ material demonstrated a power factor (S²/ρ) of approximately 16 μW/cm-K² at approximately 340 K, which is about 40% of the value for bismuth-telluride alloys at the same temperature. This power factor comprised a Seebeck coefficient (S) of approximately +150 μV/K and an example resistivity p of about 1.4 mΩ-cm. A sample of the Mg₁Ag₁Sb₁ material has also demonstrated a thermal conductivity of 11.4 milliWatts/cm-K at 340 K, which is approximately 80% of the thermal conductivity for P-type Bi₂Te₃—Sb₂Te₃ alloys at that temperature and approximately 50-60% of the thermal conductivity of pure Bi₂Te₃ at that temperature.

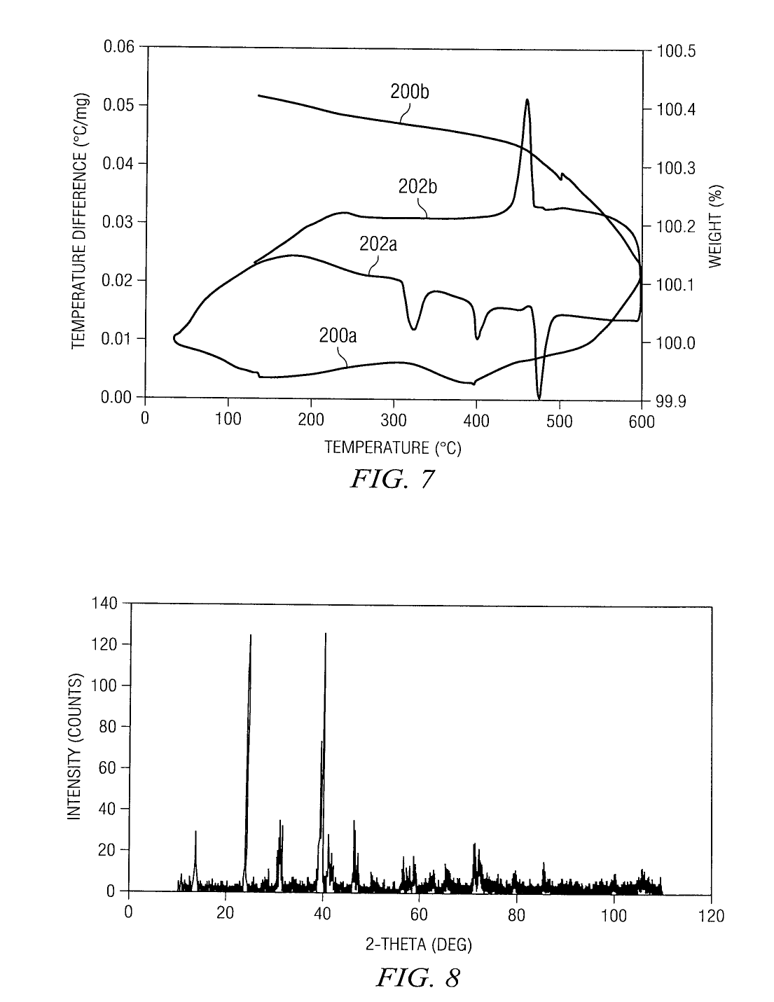

FIG. 7 illustrates a Thermogravimetric Analysis (TGA) curve 200 having a lower leg 200a and an upper leg 200b and differential thermal analysis (DTA) curve 202 having a lower leg 202a and an upper leg 202b for a nearly phase-pure sample of Mg₁Ag₁Sb₁ produced in accordance with the present disclosure. Lower legs 200a and 202a correspond to heating, while the upper legs 200b and 202b correspond to cooling. The lower leg 202a of the DTA scan shows that the Mg₁Ag₁Sb₁ material exhibited three endothermic events: a first endothermic event with its leading edge at approximately 305° C. (the “305 event”), a second endothermic event with its leading edge at approximately 385° C. (the “385 event”), and a third endothermic event with its leading edge at approximately 460° C. (the “460 event”). Endothermic events are depicted as inverted peaks on DTA curve 202 while exothermic events are depicted as upright peaks on DTA curve 202. Events due to solid-to-liquid phase change (e.g., melting) are reversed upon cooling. Consequently, the 460 event may be attributed to a solid-to-liquid phase change since it is approximately mirrored by a corresponding exothermic event occurring at approximately 460° C. on upper leg 200b of the DTA curve. One might deduce from the absence of example corresponding reversal exothermic events in upper leg 202b of the DTA curve for the other two inverted peaks (e.g., the 305 event and the 385 event) that those two endothermic events are solid-to-solid transformations.

Based on an X-ray Spectroscopy (“EDX”) of the sample illustrated in FIG. 7, it is believed that the 305 event may mark a decomposition of the Mg₁Ag₁Sb₁. In particular embodiments, it may be possible to increase the anticipated decomposition temperature at 305° C. by substituting one or more other elements for either Mg, Ag, or Sb, or a combination thereof, in the Mg₁Ag₁Sb₁ material.

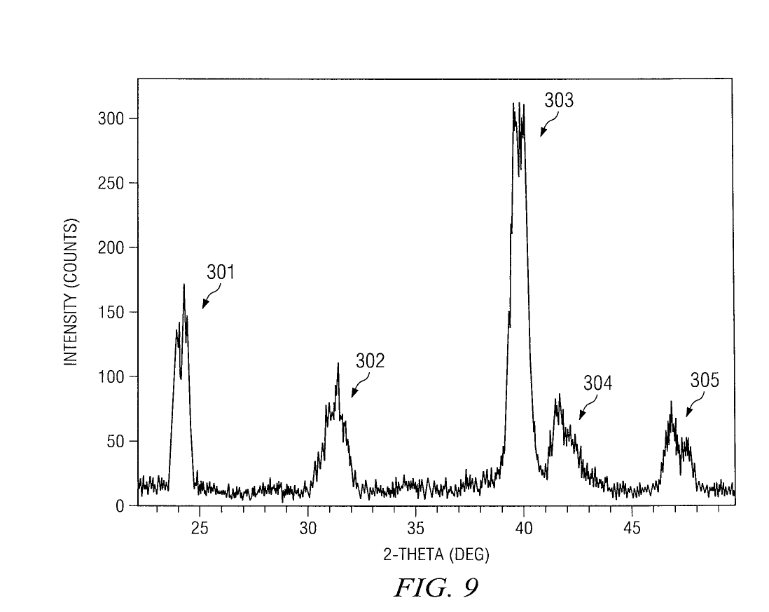

FIGS. 8 and 9 illustrate powder diffraction patterns (e.g., X-ray diffraction patterns) for two samples of Mg₁Ag₁Sb₁, heated at about 573 K. In particular, FIG. 8 illustrates a powder diffraction pattern for a sample of Mg₁Ag₁Sb₁ heated for about four days prior to collecting the diffraction patterns while FIG. 9 illustrates a powder diffraction pattern for a sample of Mg₁Ag₁Sb₁ heated for about two weeks (e.g., 14 days) prior to collecting the diffraction patterns. The scan of FIG. 8 covers 2-theta values from about 10° to about 110° and the scan of FIG. 9 covers 2-theta values from 21.5° to just over 49°.

As illustrated in FIG. 9, there are five major peaks along the horizontal axis which represents the 2-theta values (in degrees) obtained from a normal powder diffraction scan. Those peaks include a first peak 301 located at approximately 24-25 degrees 2-theta, a second peak 302 located at approximately 31-32 degrees 2-theta, a third peak 303 located at approximately 39-41 degrees 2-theta, a fourth peak 304 located at approximately 41-43 degrees 2-theta, and a fifth peak 305 located at approximately 47-48 degrees 2-theta.

It is believed that the crystal structure of Mg₁Ag₁Sb₁ is based on a primitive cubic lattice. More particularly, peak 301 has a crystal plane spacing (known as a “d-spacing” by convention) of about 3.70 Å, peak 302 has a crystal plane spacing of about 2.86 Å, peak 303 has a crystal plane spacing of about 2.26 Å, peak 304 has a crystal plane spacing of about 2.13 Å, and peak 305 has a crystal plane spacing of about 1.93 Å. The inverse squares of those d-spacings are nearly in proportion to the series of integers 3, 5, 8, 9, and 11. As will be appreciated by one of skill in the art, such a pattern is indicative of a cubic crystal structure. Table 1 below also summarizes these data values.

TABLE 1
Parameters of Peaks 301-305

| | 2-theta | d-spacing | | Integer | Miller |
|---|---|---|---|---|---|
| Peak | (degrees) | (Å) | 1/d² (Å⁻² ) | series | Indices |
| Peak 301 | 24-25 | 3.70 | 0.073 | 3 | (111) |
| Peak 302 | 31-32 | 2.86 | 0.122 | 5 | (102) |
| Peak 303 | 39-41 | 2.26 | 0.196 | 8 | (202) |
| Peak 304 | 41-43 | 2.13 | 0.220 | 9 | (122) |
| Peak 305 | 47-48 | 1.93 | 0.268 | 11 | (113) |

As indicated in Table 1, each of peaks 301-305 is associated with a Miller (or crystal) index. To calculate the integer series described above, each of the Miller indices was squared (e.g., on a per digit basis) and the resulting values added together yielding the integer series 3, 5, 8, 9, and 11. Furthermore, because the structure is cubic, the Miller indices may be interchanged with one another. For example, (102) could be equivalently represented by (201) or (210).

Besides primitive cubic lattices, there are also face-centered cubic lattices and body-centered cubic lattices. These types of cubic structures have certain restraints that must be obeyed in order for a peak to appear in the diffraction pattern. For face-centered cubic lattices, the Miller indices are either all odd or all even. For body-centered cubic lattices, the sum of all three Miller indices are even. Since the Mg₁Ag₁Sb₁ pattern does not conform to either constraint, it is believed that Mg₁Ag₁Sb₁ forms in a primitive cubic structure, though it is possible, that the crystal structure might be, for instance, a tetragonal or orthorhombic structure in which the distinct lattice constants have nearly the same value, causing the x-ray pattern to mimic that of a cubic structure.

It appears that all five major peaks (e.g., peaks 301-305) are peak-pairs. The presence of pairs of peaks in the Mg₁Ag₁Sb₁ diffraction pattern implies that variations may exist in the lattice constant, and that these variations form a bimodal distribution. Since the data of FIG. 9 were collected from a sample of Mg₁Ag₁Sb₁ that was heated for two weeks at about 573 K prior to collecting the diffraction pattern, the bimodal lattice constant distribution may be attributable to a steady state condition or, alternatively, it may be attributable to a slow merge into a single-mode distribution, due to difficult diffusion across grain boundaries. The sample of Mg₁Ag₁Sb₁ tested in FIG. 9 was created in an environment having an oxygen concentration of about 30 to about 50 parts per million, possibly leading to deposits of oxide on the surface of the sample. It is possible that samples of Mg₁Ag₁Sb₁ formed using synthesis means that permit less exposure to oxygen (e.g., preparation of Mg₁Ag₁Sb₁ samples in an environment with an oxygen concentration of about 2 ppm) may produce samples of Mg₁Ag₁Sb₁ that have lower deposits of oxide and that do not share the bimodal distribution illustrated in FIG. 9.

Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. While numerous changes may be made by those skilled in the art, such changes are encompassed within the spirit of this invention as defined by the appended claims. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. In particular, every range of values (e.g., “from about a to about b,” or, equivalently, “from approximately a to b,” or, equivalently, “from approximately a-b”) disclosed herein is to be understood as referring to the power set (the set of all subsets) of the respective range of values. The terms in the claims have their plain, ordinary meaning unless otherwise explicitly and clearly defined by the patentee.

Although the present disclosure has been described in several embodiments, a myriad of changes, substitutions, and modifications may be suggested to one skilled in the art, and it is intended that the present disclosure encompass such changes, substitutions, and modifications as fall within the scope of the present appended example claim(s).

What is claimed is:

1. A thermoelectric device, comprising a plurality of thermoelectric elements coupled between a first plate and a second plate, the plurality of thermoelectric elements being electrically interconnected with one another by a plurality of electrical interconnects, the plurality of thermoelectric elements comprising at least one thermoelectric element comprising a material having the formula AₓB_{y}C_{z}z, wherein:
A is one or more components selected from the group consisting of group II cations and mixtures thereof;
B is one or more components selected from the group consisting of group I cations and mixtures thereof;
C is one or more components selected from the group consisting of group V anions and mixtures thereof; and
x, y, and z are molar ratios.

2. The thermoelectric device of claim 1, wherein
A is one or more components selected from the group consisting of Mg, Ca, Sr, Ba, Eu, Yb, Ti, Mn, Fe, Ni, Cu, Zn, Cd, Hg, and mixtures thereof;
B is one or more components selected from the group consisting of Na, K, Rb, Cs, Cu, Ag, Au, and mixtures thereof; and
C is one or more components selected from the group consisting of As, Sb, Bi, and mixtures thereof.

3. The thermoelectric device of claim 2, wherein x is about 0.9 to about 1.1, y is about 0.9 to about 1.1, and z is about 0.9 to about 1.1.

4. The thermoelectric device of claim 1, wherein:
A comprises Mg, B comprises Ag, and C comprises Sb.

5. The thermoelectric device of claim 4, wherein x is about 1, y is about 1, and z is about 1.

6. The thermoelectric device of claim 2, wherein the material exhibits P-type conduction.

7. The thermoelectric device of claim 2, wherein the material exhibits a ZT value of about 0.5 at about 340 K.

8. The thermoelectric device of claim 2, wherein the material exhibits a power factor of about 16 μW/cm-K² at about 340 K.

9. A thermoelectric element, comprising a material having the formula AₓB_{y}C_{z}, wherein:
A is one or more components selected from the group consisting of group II cations and mixtures thereof;
B is one or more components selected from the group consisting of group I cations and mixtures thereof;
C is one or more components selected from the group consisting of group V anions and mixtures thereof; and
x, y, and z are molar ratios.

10. The thermoelectric element of claim 9, wherein
A is one or more components selected from the group consisting of Mg, Ca, Sr, Ba, Eu, Yb, Ti, Mn, Fe, Ni, Cu, Zn, Cd, Hg, and mixtures thereof;
B is one or more components selected from the group consisting of Na, K, Rb, Cs, Cu, Ag, Au, and mixtures thereof; and
C is one or more components selected from the group consisting of As, Sb, Bi, and mixtures thereof.

11. The thermoelectric element of claim 10, wherein x is about 0.9 to about 1.1, y is about 0.9 to about 1.1, and z is about 0.9 to about 1.1.

12. The thermoelectric element of claim 9, wherein:
A comprises Mg, B comprises Ag, and C comprises Sb.

13. The thermoelectric element of claim 12, wherein x is about 1, y is about 1, and z is about 1.

14. A method, comprising:
providing a material having the formula AₓB_{y}C_{z}, x, y, and z being molar ratios, wherein:
A is one or more components selected from the group consisting of group II cations and mixtures thereof;
B is one or more components selected from the group consisting of group I cations and mixtures thereof;
C is one or more components selected from the group consisting of group V anions and mixtures thereof; and
x, y, and z are molar ratios; and
using the material as a thermoelectric material.

15. The method of claim 14, wherein:
A is one or more components selected from the group consisting of Mg, Ca, Sr, Ba, Eu, Yb, Ti, Mn, Fe, Ni, Cu, Zn, Cd, Hg, and mixtures thereof;
B is one or more components selected from the group consisting of Na, K, Rb, Cs, Cu, Ag, Au, and mixtures thereof; and
C is one or more components selected from the group consisting of As, Sb, Bi, and mixtures thereof.

16. The method of claim 15, wherein x is about 0.9 to about 1.1, y is about 0.9 to about 1.1, and z is about 0.9 to about 1.1.

17. The method of claim 16, wherein using the material as a thermoelectric material comprises applying electrical current to the material and allowing the material to generate a temperature difference between a first side of the material and a second side of the material.

18. The method of claim 16, wherein using the material as a thermoelectric material comprises applying a temperature difference to the material and allowing the material to generate electricity.

19. The method of claim 14, wherein:
A comprises Mg, B comprises Ag, and C comprises Sb.

20. The method of claim 19, wherein x is about 1, y is about 1, and z is about 1.

21. A thermoelectric device, comprising a plurality of thermoelectric elements coupled between a first plate and a second plate, the plurality of thermoelectric elements being electrically interconnected with one another by a plurality of electrical interconnects, the plurality of thermoelectric elements comprising at least one thermoelectric element comprising a material having the formula A_{x-w}B_{y+w}C_{z-w}D_{w}, wherein:
A is one or more components selected from the group consisting of group II cations and mixtures thereof;
B is one or more components selected from the group consisting of group I cations and mixtures thereof;
C is one or more components selected from the group consisting of group V anions and mixtures thereof;
D is one or more components selected from the group consisting of group VI anions and mixtures thereof; and
w, x, y, and z are molar ratios.

22. The thermoelectric device of claim 21, wherein
A is one or more components selected from the group consisting of Mg, Ca, Sr, Ba, Eu, Yb, Ti, Mn, Fe, Ni, Cu, Zn, Cd, Hg, and mixtures thereof;
B is one or more components selected from the group consisting of Na, K, Rb, Cs, Cu, Ag, Au, and mixtures thereof;
C is one or more components selected from the group consisting of As, Sb, Bi, and mixtures thereof; and
D is one or more components selected from the group consisting of Se, Te, and mixtures thereof.

23. The thermoelectric device of claim 21 wherein w is about 0 to about 1, x is about 0.9 to about 1.1, y is about 0.9 to about 1.1, and z is about 0.9 to about 1.1.

24. A thermoelectric device, comprising a plurality of thermoelectric elements coupled between a first plate and a second plate, the plurality of thermoelectric elements being electrically interconnected with one another by a plurality of electrical interconnects, the plurality of thermoelectric elements comprising at least one thermoelectric element comprising a material having the formula A_{x+w}B_{y-w}C_{z-w}E_{w}, wherein:
A is one or more components selected from the group consisting of group II cations and mixtures thereof;
B is one or more components selected from the group consisting of group I cations and mixtures thereof;
C is one or more components selected from the group consisting of group V anions and mixtures thereof;
E is one or more components selected from the group consisting of group IV anions and mixtures thereof; and
w, x, y, and z are molar ratios.

25. The thermoelectric device of claim 24, wherein
A is one or more components selected from the group consisting of Mg, Ca, Sr, Ba, Eu, Yb, Ti, Mn, Fe, Ni, Cu, Zn, Cd, Hg, and mixtures thereof;
B is one or more components selected from the group consisting of Na, K, Rb, Cs, Cu, Ag, Au, and mixtures thereof;
C is one or more components selected from the group consisting of As, Sb, Bi, and mixtures thereof; and
E is one or more components selected from the group consisting of Si, Ge, Sn, Pb, and mixtures thereof.

26. The thermoelectric device of claim 24 wherein w is about 0 to about 1, x is about 0.9 to about 1.1, y is about 0.9 to about 1.1, and z is about 0.9 to about 1.1.

27. A thermoelectric device, comprising a plurality of thermoelectric elements coupled between a first plate and a second plate, the plurality of thermoelectric elements being electrically interconnected with one another by a plurality of electrical interconnects, the plurality of thermoelectric elements comprising at least one thermoelectric element comprising a material having the formula (AₓB_{y}C_{z}z)₁₋ₐ(FᵤCᵥ)ₐ, wherein:
A is one or more components selected from the group consisting of group II cations and mixtures thereof;
B is one or more components selected from the group consisting of group I cations and mixtures thereof;
C is one or more components selected from the group consisting of group V anions and mixtures thereof;
F is one or more components selected from the group consisting of group III cations and mixtures thereof, and
a, u, v, x, y, and z are molar ratios.

28. The thermoelectric device of claim 27, wherein
A is one or more components selected from the group consisting of Mg, Ca, Sr, Ba, Eu, Yb, Ti, Mn, Fe, Ni, Cu, Zn, Cd, Hg, and mixtures thereof,
B is one or more components selected from the group consisting of Na, K, Rb, Cs, Cu, Ag, Au, and mixtures thereof:
C is one or more components selected from the group consisting of As, Sb, Bi, and mixtures thereof; and
F is one or more components selected from the group consisting of Al, Ga, In, and mixtures thereof.

29. The thermoelectric device of claim 27 wherein a is about 0 to about 0.5, u is about 0.9 to about 1.1, v is about 0.9 to about 1.1, x is about 0.9 to about 1.1, y is about 0.9 to about 1.1, and z is about 0.9 to about 1.1.
